(19) United States
(12) Patent Application Publication
(10) Pub. No.: US 2026/0358705 A1
(43) Pub. Date: Nov. 12, 2026

(54) PHOTO RESIST PROCESSES EMPLOYING BISMUTH IODIDE PEROVSKITE MATERIALS

(71) Applicant: Intel Corporation, Santa Clara, CA (US)

(72) Inventors: Charles MOKHTARZADEH, Portland, OR (US); Rambert NAHM, Portland, OR (US); Scott SEMPRONI, Fair Lawn, NJ (US); I-Cheng TUNG, Hillsboro, OR (US); Scott B. CLENDENNING, Portland, OR (US); Francesca BARD, Portland, OR (US); Annika JANSEN, Portland, OR (US)

(21) Appl. No.: 19/202,468

(22) Filed: May 8, 2025

(51) Int. Cl. G03F 7/004; G03F 7/00; G03F 7/26

(52) U.S. Cl. CPC G03F 7/0043; G03F 7/0035; G03F 7/265; G03F 7/70358

(57) ABSTRACT

Provided are methods and compounds for using bismuth-iodide perovskite materials as photo-resists in a lithographic process for making a semiconductor wafer.

### TECHNICAL FIELD

The present disclosure generally relates to semiconductor lithography and more particularly to photo resist materials and processes.

### BRIEF DESCRIPTION OF THE DRAWINGS

The disclosure may best be understood by referring to the following description and accompanying drawings that are used to illustrate embodiments. In the drawings:

FIG. 1 is a diagram schematically illustrating a portion of a lithographic manufacturing process for a semiconductor device in accordance with some embodiments.

FIG. 2 is a chart depicting computed EUV absorbance values for various different materials including bismuth iodide perovskite materials in accordance with some embodiments.

FIG. 3A is a diagram showing exemplary R group variants that can be used as a polymeric precursor in a bismuth iodide perovskite resist material in accordance with some embodiments.

FIG. 3B is a diagram showing exemplary polymerizable ammonium iodide salts that can be combined with bismuth-iodide to form a bismuth-iodide perovskite material in accordance with some embodiments.

FIG. 4 is a diagram illustrating a solution-phase approach for generating a bismuth-iodide perovskite resist material in accordance with some embodiments.

FIG. 5 is a photo showing an exemplary spin-coated bismuth-iodide perovskite material with a film thickness averaging 20 nm±1.5 nm center to edge.

### DETAILED DESCRIPTION

As the critical dimensions for lithographic patterning in semiconductor manufacturing continue to shrink, advancements in extreme ultraviolet (EUV) and high numerical aperture extreme ultraviolet (NA EUV) patterning are being developed. As a result of these advancements, the need for new resist materials that exhibit increased efficiency with EUV photons as well as greater stability is only heightened.

Within the field of EUV and High NA EUV patterning, metal oxide resists have widely been dominated by Sn-oxide based materials. These compounds have been effective but are limited as EUV and NA EUV feature pattern feature dimensions continue to shrink. Among other things, they suffer from instability when exposed to ambient conditions and thus exhibit unwanted reactivity, which in turn has a negative effect on patterning efficiency and dose-to-dose reproducibility. Additionally, thinner films with higher EUV absorbing materials, are needed to address depth of focus requirements for higher NA EUV processing. Accordingly, new approaches would be desired.

In some embodiments, Bismuth-iodide based perovskite materials are provided for use as photo resists, e.g., for EUV and/or high NA EUV patterning applications. Being substantially composed of high Z elements, they can provide relatively large EUV light absorption cross sections and facilitate favorable light sensitivity. In some embodiments, they may be generated either in solution or in a vapor phase, e.g., through chemical vapor deposition (CVD) or atomic layer deposition (ALD)).

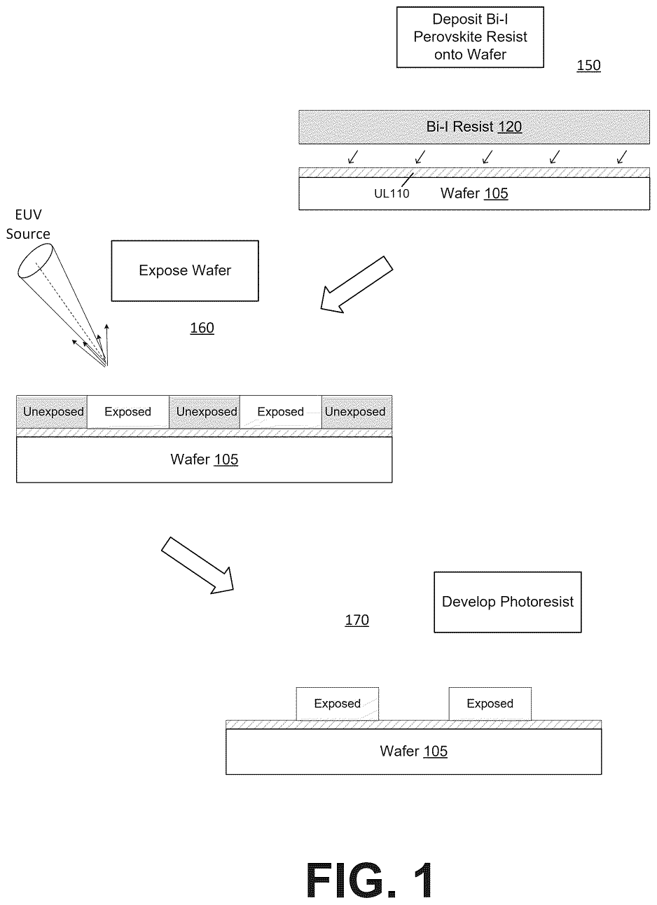

FIG. 1 is a diagram schematically illustrating a portion of a lithographic manufacturing process for a semiconductor device in accordance with some embodiments. During the manufacture of semiconductor devices, fine patterns of features (e.g., integrated circuit features) can be formed on a surface of a wafer 105 by patterning the surface of the wafer and etching material from the wafer surface using, for example, gas and/or wet phase etching processes.

As shown at 150, a Bismuth-Iodide perovskite photoresist (hereinafter referred to as BIP resist) layer 120 is used to pattern a surface of the wafer 105 prior to etching. The resist layer 120 is applied to a surface, usually on top of an underlayer material 110, which among other things, can serve as an adhesive to adhere the photoresist to the wafer, or exposed layer, surface. For example, a thin (e.g., mono-molecular) underlayer may be grafted onto the currently exposed surface of the wafer. (It should be appreciated, however, that depending on specific materials, conditions and/or layers of a wafer manufacture process, an underlayer may or may not be used.)

As will be discussed further below, in some embodiments, Bismuth-Iodide perovskite (BIP) materials may be used as photo resist materials. They may be implemented in any suitable manner. For example, they may be formed in solution and applied using a spin coating method, or they may be formed as part of a chemical vapor deposition (CVD) process.

Returning back to the diagram, from here, at 160, the BIP photoresist is then exposed to radiation from a mask having a desired feature pattern. For example, extreme ultraviolet (EUV) techniques may be implemented to develop circuit feature patterns having relatively small pattern features (e.g., 10 nm or less). The radiation (EUV) pattern is projected onto the resist, exposing the pattern, or non-pattern, portions, depending on whether a positive or negative BIP resist material is used. The patterned resist layer may then go through a post exposure bake (PEB) stage, e.g., 120 degrees C. for 1 minute.

From here, either the exposed (positive) or non-exposed (negative) portions are removed using a development process. This is represented at 170. With this example, a negative BIP resist is used where the unexposed portions are removed. Thus, as shown at 170, the exposed resist portions remain. In some embodiments, the underlayer 110 may also be removed. From here, layers with desired feature patterns may be built up through alternating etch and deposition processes using BIP photo-resist, and possibly other resist materials, as dictated by particular process stage considerations.

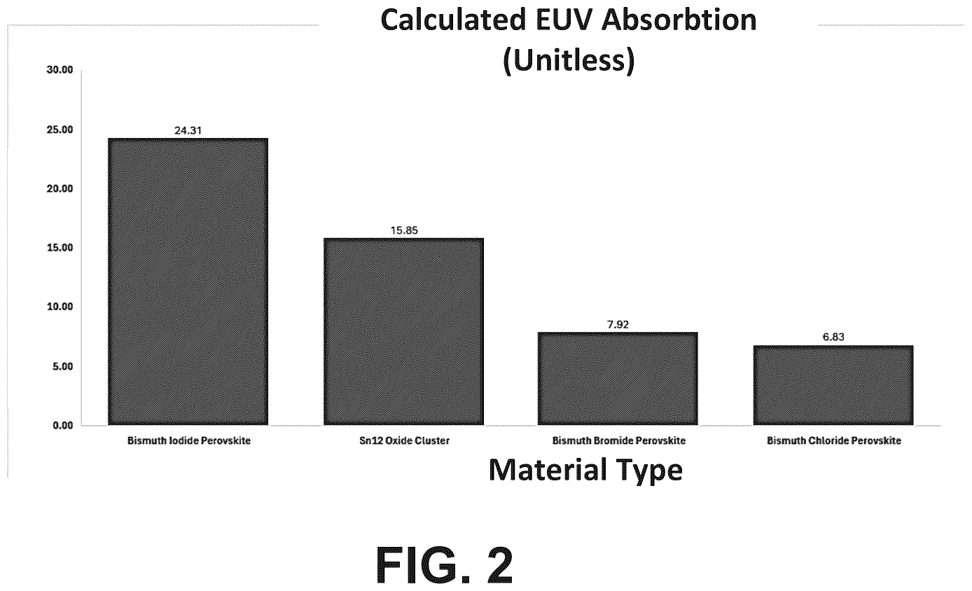

As mentioned above, bismuth-iodide perovskites can serve as effective photo-resist materials, for among other reasons, because both bismuth and iodide have relatively large EUV cross sections, which can allow them to work at lower doses. This is illustrated in FIG. 2, which is a chart depicting computed EUV absorbance values for various different materials including bismuth iodide perovskite materials in accordance with some embodiments. Compared to the other materials, the bismuth iodide perovskites show a calculated 53% or more increase in EUV absorption as a result, for example, of both greater film density and higher EUV cross sections for Bismuth and Iodine.

Additionally, by removing specific M—C bonds from bismuth compound cores, the materials can display greater stability to ambient conditions, especially when compared to the Sn-carbon bonds present in existing materials, which are well known to exhibit air-sensitivity and facile Sn—C bond homolysis.

It should be appreciated that a variety of different suitable BIP compositions may be employed for photo-resist applications as disclosed herein. For example, a suitable bismuth iodide perovskite (BIP) material may include a bismuth-iodide cluster coupled with a polymeric ammonium cation such as a compound in conformance with the formula: MₓBi_{y}I_{z} (where x=2-6, y=2-10, z=8-30, e.g., M₃Bi₂I₉). Here, M is a polymerizable ammonium cation, e.g., RNH₃+, R₂NH₂+, or R₃NH+ (primary, secondary, and tertiary ammonium cations, respectively), with R being any suitable polymeric precursor component to facilitate photonically activated cross linkable, or cleavable, groups for negative or positive resist lithography.

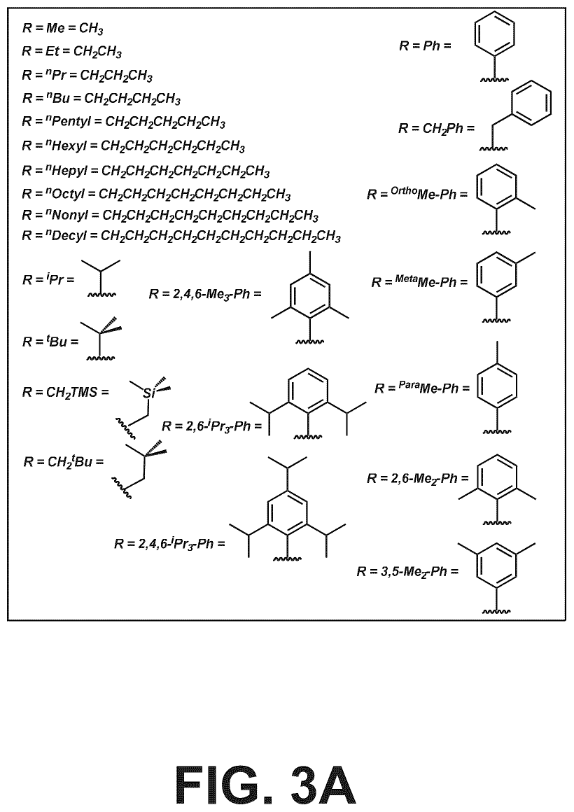

With reference to FIGS. 3A and 3B, FIG. 3A is a diagram showing exemplary R group variants that can be used as a polymeric precursor in a bismuth iodide perovskite resist material for the polymeric ammonium cations. FIG. 3B is a diagram showing exemplary polymerizable ammonium iodide salts that can be combined with bismuth-iodide (e.g., BiI₃) to form a bismuth-iodide perovskite material in accordance with some embodiments. As illustrated in FIG. 3B, suitable ammonium iodide salts may include: tri-vinyl-ammonium-Iodide, 4-ammonium iodide styrene, pyrrolidinium iodide, n-(3-aminopropyl) methacrylamide hydrochloride, pyridinium iodide, N-(3-aminopropyl)methoctramine hydroiodide, 4-vinyl pyridinium iodide, 2-di-isopropyl-ammonium-methyl-methacrylate iodide, protonated pyrazole, 2-N-morpholino ethyl methacrylate iodide, and olefinic ammonium iodide.

In addition to the higher absorption that the bismuth-iodide perovskites provide, they also provide the opportunity for unique EUV chemistry. By virtue of being able to differentiate physical properties through selection of an appropriate ammonium salt, incorporation of polymerizable ammonium salt units can provide an additional option for improving patterning. For example, use of styrene units featuring ammonium iodide units may provide an option for incorporating polymerizable monomer units that can take advantage of secondary electron generation to create highly “cross linked” films for negative tone resist processes.

In addition, it is noteworthy that by moving the organic substituents to the ammonium cations of a bismuth-iodide cluster (e.g., [Bi₂I₉]₃) can facilitate an ability to modulate not only the physical properties of the resist material (e.g. solubility, crystallinity, thermal stability) but also, it can provide for additional chemical reactivity control for the resist material.

It is also noted that with their ability to provide smaller resist film thicknesses, BIP resists can be used for high numeric aperture (NA) EUV and hyper NA EUV patterning schemes. In this way, they can be used for resists that can meet or exceed current patterning dose requirements. As dose typically is proportional to the density of a film, incorporation of bismuth and Iodine (some of the highest Z elements on the periodic table) can provide the ability to generate films of the required density at thinner film thickness to meet aggressive manufacturing requirements.

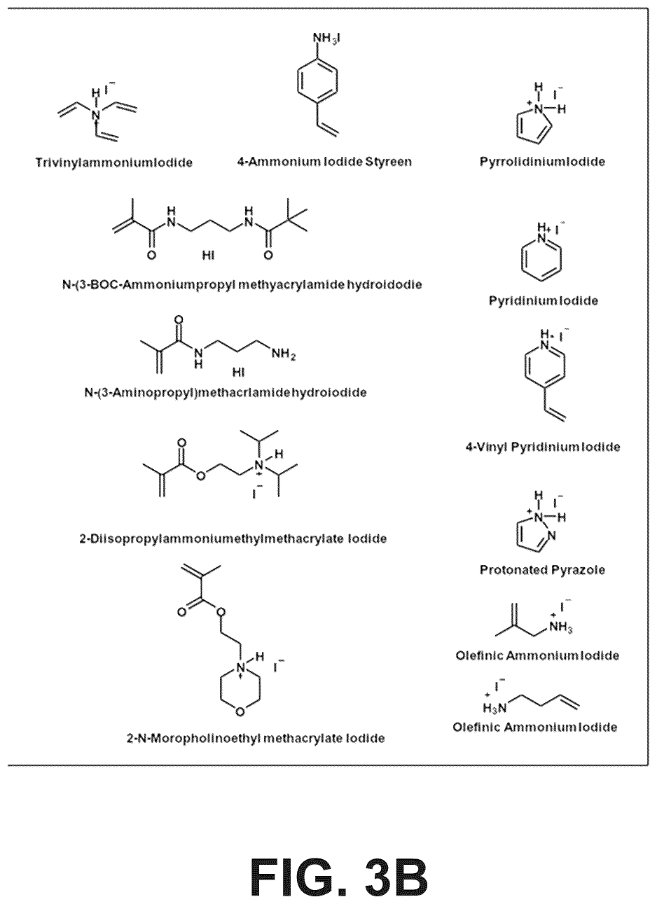

FIG. 4 is a diagram illustrating a solution-phase approach for generating a bismuth-iodide perovskite resist material in accordance with some embodiments. This diagram shows how the addition of polymeric ammonium iodide salts with bismuth-iodide (BiI₃) in a polar aprotic solvent can be used to generate BIP resist materials. Reference is made to FIG. 3B for some examples of suitable ammonium iodide salts. Likewise, any suitable polar aprotic solvents may be used, and in some embodiments, they may include DMF (dimethylformamide), DMSO (dimethyl sulfoxide), and PGMEA (propylene glycol methyl ether acetate). With this example, the polymeric ammonium iodide salt reacts with the bismuth-iodide. In some embodiments, the reaction may be enhanced with sonication, leading to the formation of a deep orange solution of a bismuth iodide perovskite (e.g., M₃Bi₂I₉) material that can be used as a resist material.

For example, the resulting BIP material may then be spin coated onto a wafer substrate surface. These materials can be coated with desirable thickness uniformity across a wafer. Moreover, they demonstrate good air stability with minimum film thickness changes, e.g., when exposed to air over 24 hour cycles, in contrast with conventional Sn based metal oxide resist materials, which typically show appreciable compositional changes over as little as 1-2 hour time frames that lead to problematic EUV patterning process variation. This is of particular importance when considering high NA multi-pass EUV patterning where EUV exposures may be stepped onto a wafer with delay times on the order of minutes.

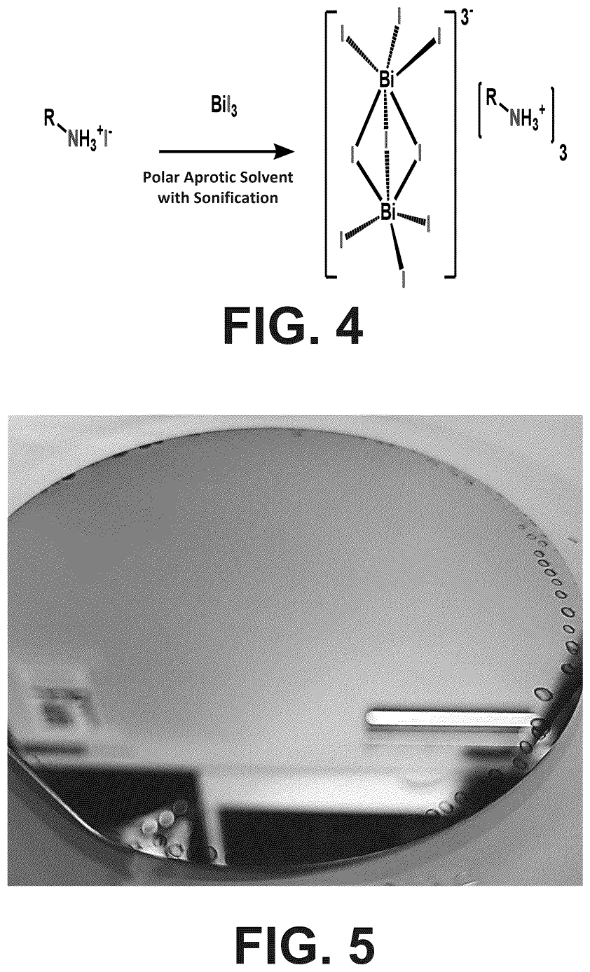

FIG. 5 is a photo showing an exemplary spin-coated bismuth-iodide perovskite material with a film thickness averaging 20 nm, ±1.5 nm, center to edge. With this example, benzylammonium was used as R-group counter ions for the bismuth-iodide-3 clusters.

In some embodiments, a chemical vapor deposition (CVD) or an atomic layer deposition (ALD) method may be employed to form a BIP resist layer onto a wafer. For example, a vacuum deposition system could be employed. With such a system, the vacuum can be used to pull in a controlled amount of constituent components to form the BIP layer. Another benefit of using a CVD, or ALD, method is that it can cause the BIP to be grafted onto the surface as it is applied, without necessarily having to be baked as may be the case with a spin coat application.

In some embodiments, a BIP resist layer may be deposited in a gas phase, e.g., without requiring a solvent. For example, iodic acid (HI), a polymerizable ammonium iodide salt (FIG. 3B), and BiI3 may be combined in a vapor phase chamber. With this approach: R—NH₂+HI (iodic acid)→R—NH₃, add this reacts with BiI₃ to create the bismuth iodide perovskite resist. The gas flow rates, temperature, chamber pressure, wafer spin, and other factors may be tuned to achieve desired results. In some embodiments, co-flowing bismuth-alkyl precursors [(BiR)₃] wit iodic acid (HI) and an appropriate amine can provide a uniform BIP thin film.

Another aspect of using BIP resist materials into semiconductor manufacturing processes is the use of a suitable develop process to remove unexposed (or exposed) material. In some embodiments, for removing unexposed material (negative resist process), a dry development approach may be employed. For example, a vapor phase etch may be used. However, bismuth halide materials such as (e.g., BiX₃) typically have low volatility properties.

To address this issue, in some embodiments, bismuth iodide perovskites may be etched with the use of an AlR₃ etch material. AlR₃ refers to tri-organoaluminium compounds where the aluminum atom is bonded to three organic substituents (R groups). These R groups may be any suitable organo substituents such as alkyl or aryl groups. For example, suitable R groups may include simple alkyl groups such as methyl, ethyl, and isobutyl groups and bulky aryl groups such as mesityl (2,4,6-trimethylphenyl) or other sterically hindered groups.

With the use of vapor phase AlR3 etching, a sigma bond metathesis mechanism may be exploited where the alkyl aluminum species transfers 1-3 alkyl groups to the bismuth centers while simultaneously absorbing Iodide due to the high propensity for Al—X bond formation. With simultaneous heating volatilization of the resulting bismuth alkyl species, the resulting aluminum-iodide and [R₄N]I results in a vapor phase etch of the unexposed BIP material.

In some embodiments, a wet develop process could alternatively or additionally be used. For example, upon exposure, organic solvents such as dimethyl sulfoxide (DMSO), dimethylformamide (DMF) or propylene glycol monomethyl ether acetate (PGMEA) could be used to remove unexposed bismuth-iodide perovskite resist materials.

Illustrative examples of the technologies disclosed herein are provided below. An embodiment of the technologies may include any one or more, and any compatible combination of, the examples described below.

Example 1 is a method including: depositing a photo-resist including a bismuth iodide perovskite (BIP) material onto a surface of a semiconductor wafer; scanning a pattern onto the photo resist resulting in exposed and unexposed photo resist portions; and at least partially removing one of the exposed or unexposed photo resist portions.

Example 2 includes the subject matter of example 1, and wherein the BIP material includes BIP compounds with polymeric ammonium cations coupled with bismuth-iodide clusters.

Example 3 includes the subject matter of any of examples 1-2, and wherein the BIP compounds are in accordance with the formula: M3Bi2I9, where M represents the polymeric ammonium cations.

Example 4 includes the subject matter of any of examples 1-3, and wherein the polymeric ammonium cations include at least one of RNH3+, R2NH2+, or R3NH+, where R is a polymeric precursor to facilitate photonically activated cross linkable, or cleavable, groups for negative or positive resist lithography.

Example 5 includes the subject matter of any of examples 1-4, and wherein the BIP material is deposited onto the semiconductor wafer surface using a spin coating process.

Example 6 includes the subject matter of any of examples 1-5, and wherein the BIP material is deposited onto the semiconductor wafer surface using a chemical vapor deposition or atomic layer deposition process.

Example 7 includes the subject matter of any of examples 1-6, and wherein the BIP material is formed in solution by combining a polymerizable ammonium iodide salt with bismuth-iodide.

Example 8 includes the subject matter of any of examples 1-7, and wherein the polymerizable ammonium iodide salt includes at least one of tri-vinyl-ammonium-Iodide, 4-ammonium iodide styrene, pyrrolidinium iodide, n-(3-aminopropyl) methacrylamide hydrochloride, pyridinium iodide, N-(3-aminopropyl)methoctramine hydroiodide, 4-vinyl pyridinium iodide, 2-di-isopropyl-ammonium-methyl-methacrylate iodide, protonated pyrazole, 2-N-morpholino ethyl methacrylate iodide, or olefinic ammonium iodide.

Example 9 includes the subject matter of any of examples 1-8, and comprising using a dry vapor-phase etch process to at least partially removing one of the exposed or unexposed photo resist portions.

Example 10 includes the subject matter of any of examples 1-9, and wherein the dry vapor-phase etch process includes using an alkyl aluminum species as a reactant.

Example 11 is a method that includes: scanning a pattern onto a bismuth iodide perovskite (BIP) photo resist layer generating exposed and unexposed BIP photo resist portions; and at least partially removing the unexposed BIP photo resist portions by etching them using a vapor-phase process with a tri-organoaluminium compound.

Example 12 includes the subject matter of example 11, and wherein the tri-organoaluminium compound includes an R-group substituent selected from a group including alkyl and aryl group substituents.

Example 13 includes the subject matter of any of examples 11-12, and wherein the R-group substituent includes at least one substituent selected from a methyl, ethyl, isobutyl, or mesityl group.

Example 14 is a process of making an integrated circuit apparatus. The process includes: depositing a photo-resist including a bismuth iodide perovskite (BIP) material onto a surface of a semiconductor wafer; scanning a pattern corresponding to electrical circuit features onto the photo resist resulting in exposed and unexposed photo resist portions; at least partially removing one of the exposed or unexposed photo resist portions; and repeating the previous actions two or more times to build integrated circuit layers upon the wafer.

Example 15 includes the subject matter of example 14, and wherein the BIP material includes BIP compounds with polymeric ammonium cations coupled with bismuth-iodide clusters.

Example 16 includes the subject matter of any of examples 14-15, and wherein the BIP compounds are in accordance with the formula: M3Bi2I9, where M represents the polymeric ammonium cations.

Example 17 includes the subject matter of any of examples 14-16, and wherein the polymeric ammonium cations include at least one of RNH3+, R2NH2+, or R3NH+, where R is a polymeric precursor to facilitate photonically activated cross linkable, or cleavable, groups for negative or positive resist lithography.

Example 18 includes the subject matter of any of examples 14-17, and wherein the BIP material is deposited onto the semiconductor wafer surface using a spin coating process.

Example 19 includes the subject matter of any of examples 14-18, and wherein the BIP material is deposited onto the semiconductor wafer surface using a chemical vapor deposition or atomic layer deposition process.

Example 20 includes the subject matter of any of examples 14-19, and wherein the BIP material is formed in solution by combining a polymerizable ammonium iodide salt with bismuth-iodide.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

As used in this specification, the term “embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

What is claimed is:

1. A method, comprising:
depositing a photo-resist including a bismuth iodide perovskite (BIP) material onto a surface of a semiconductor wafer;
scanning a pattern onto the photo resist resulting in exposed and unexposed photo resist portions; and
at least partially removing one of the exposed or unexposed photo resist portions.

2. The method of claim 1, wherein the BIP material includes BIP compounds with polymeric ammonium cations coupled with bismuth-iodide clusters.

3. The method of claim 2, wherein the BIP compounds are in accordance with the formula: M3Bi2I9, where M represents the polymeric ammonium cations.

4. The method of claim 3, wherein the polymeric ammonium cations include at least one of RNH3+, R2NH2+, or R3NH+, where R is a polymeric precursor to facilitate photonically activated cross linkable, or cleavable, groups for negative or positive resist lithography.

5. The method of claim 1, wherein the BIP material is deposited onto the semiconductor wafer surface using a spin coating process.

6. The method of claim 1, wherein the BIP material is deposited onto the semiconductor wafer surface using a chemical vapor deposition or atomic layer deposition process.

7. The method of claim 1, wherein the BIP material is formed in solution by combining a polymerizable ammonium iodide salt with bismuth-iodide.

8. The method of claim 7, wherein the polymerizable ammonium iodide salt includes at least one of tri-vinyl-ammonium-Iodide, 4-ammonium iodide styrene, pyrrolidinium iodide, n-(3-aminopropyl) methacrylamide hydrochloride, pyridinium iodide, N-(3-aminopropyl)methoctramine hydroiodide, 4-vinyl pyridinium iodide, 2-di-isopropyl-ammonium-methyl-methacrylate iodide, protonated pyrazole, 2-N-morpholino ethyl methacrylate iodide, or olefinic ammonium iodide.

9. The method of claim 1, comprising using a dry vapor-phase etch process to at least partially removing one of the exposed or unexposed photo resist portions.

10. The method of claim 9, wherein the dry vapor-phase etch process includes using an alkyl aluminum species as a reactant.

11. A method, comprising:
scanning a pattern onto a bismuth iodide perovskite (BIP) photo resist layer generating exposed and unexposed BIP photo resist portions; and
at least partially removing the unexposed BIP photo resist portions by etching them using a vapor-phase process with a tri-organoaluminium compound.

12. The method of claim 11, wherein the tri-organoaluminium compound includes an R-group substituent selected from a group including alkyl and aryl group substituents.

13. The method of claim 12, wherein the R-group substituent includes at least one substituent selected from a methyl, ethyl, isobutyl, or mesityl group.

14. A process of making an integrated circuit apparatus, comprising:
depositing a photo-resist including a bismuth iodide perovskite (BIP) material onto a surface of a semiconductor wafer;
scanning a pattern corresponding to electrical circuit features onto the photo resist resulting in exposed and unexposed photo resist portions;
at least partially removing one of the exposed or unexposed photo resist portions; and
repeating the previous actions two or more times to build integrated circuit layers upon the wafer.

15. The process of claim 14, wherein the BIP material includes BIP compounds with polymeric ammonium cations coupled with bismuth-iodide clusters.

16. The process of claim 15, wherein the BIP compounds are in accordance with the formula: M3Bi2I9, where M represents the polymeric ammonium cations.

17. The process of claim 16, wherein the polymeric ammonium cations include at least one of RNH3+, R2NH2+, or R3NH+, where R is a polymeric precursor to facilitate photonically activated cross linkable, or cleavable, groups for negative or positive resist lithography.

18. The process of claim 14, wherein the BIP material is deposited onto the semiconductor wafer surface using a spin coating process.

19. The process of claim 14, wherein the BIP material is deposited onto the semiconductor wafer surface using a chemical vapor deposition or atomic layer deposition process.

20. The process of claim 14, wherein the BIP material is formed in solution by combining a polymerizable ammonium iodide salt with bismuth-iodide.
